(19) United States
(12) Patent Application Publication
(10) Pub. No.: US 2024/0224530 A1
(43) Pub. Date: Jul. 4, 2024

(54) VERTICAL NAND FLASH MEMORY DEVICE

(71) Applicant: SAMSUNG ELECTRONICS CO., LTD., Suwon-si (KR)

(72) Inventors: Seungdam HYUN, Suwon-si (KR); Kyunghun KIM, Suwon-si (KR); Sunho KIM, Suwon-si (KR); Hyungyung KIM, Suwon-si (KR); Kwangmin PARK, Suwon-si (KR); Seungyeul YANG, Suwon-si (KR); Gukhyon YON, Suwon-si (KR); Minhyun LEE, Suwon-si (KR); Seokhoon CHOI, Suwon-si (KR); Hoseok HEO, Suwon-si (KR)

(73) Assignee: SAMSUNG ELECTRONICS CO., LTD., Suwon-si (KR)

(21) Appl. No.: 18/215,533

(22) Filed: Jun. 28, 2023

(30) Foreign Application Priority Data
Jan. 4, 2023 (KR) 10-2023-0001322

(51) Int. Cl. H10B 43/35; G11C 16/04; H01L 29/423; H10B 43/10; H10B 43/27

(52) U.S. Cl. CPC H10B 43/35; G11C 16/0483; H01L 29/4234; H10B 43/10; H10B 43/27

(57) ABSTRACT

A vertical NAND flash memory device includes a plurality of cell arrays, where each cell array of the plurality of cell arrays includes a channel layer, a charge trap layer provided on the channel layer, the charge trap layer including a matrix comprising a dielectric and a charge trap material in the matrix and including anti-ferroelectric nanocrystals or ferroelectric nanocrystals, and a plurality of gate electrodes provided on the charge trap layer.

### CROSS-REFERENCE TO RELATED APPLICATION

This application is based on and claims priority under 35 U.S.C. § 119 to Korean Patent Application No. 10-2023-0001322, filed on Jan. 4, 2023, in the Korean Intellectual Property Office, the disclosure of which is incorporated by reference herein in its entirety.

### BACKGROUND

### 1. Field

The disclosure relates to a vertical NAND flash memory device.

### 2. Description of the Related Art

As related art hard disks have been replaced by solid state drives (SSDs), a NAND flash memory device, which is a nonvolatile memory device, has been widely commercialized. Recently, a vertical NAND flash memory device in which a plurality of memory cells are stacked in a direction perpendicular to a substrate has been developed in accordance with the trend of compact size and high integration.

In a vertical NAND flash memory device, a charge transfer between memory cells may occur due to an increase in the number of stacked stages of memory cells and a decrease in the height of the memory cells, and such charge transfer may deteriorate the charge retention of the memory cells.

### SUMMARY

Provided is a vertical NAND flash memory device.

Additional aspects will be set forth in part in the description which follows and, in part, will be apparent from the description, or may be learned by practice of the presented embodiments of the disclosure.

According to an aspect of the disclosure, a vertical NAND flash memory device may include a plurality of cell arrays, where each cell array of the plurality of cell arrays may include a channel layer, a charge trap layer provided on the channel layer, the charge trap layer including a matrix comprising a dielectric and a charge trap material in the matrix and including anti-ferroelectric nanocrystals or ferroelectric nanocrystals, and a plurality of gate electrodes provided on the charge trap layer.

The charge trap material may include a flurite-based material, a perovskite-based material, or a wurtzite-based material.

The flurite-based material may include HfO₂ or ZrO₂.

The flurite-based material may include a dopant.

The dopant may include at least one of Al, Ga, Co, Ni, Mg, In, La, Y, Nd, Sm, Er, Sr, Ba, Gd, Ge, N, and Si.

The flurite-based material may include an anti-ferroelectric material having a tetragonal system structure or a ferroelectric material having an orthorhombic system structure.

The flurite-based material may include nanocrystals having a grain size of about 1 nm to about 7 nm.

The perovskite-based material may include a material having a composition of ABO₃, and where A and B may include metal elements.

The perovskite-based material may include at least one of PbZrO₃, PbTiO₃, BaTiO₃, SrTiO₃ and CaTiO₃.

The wurtzite-based material may include AlN, GaN or InN.

The wurtzite-based material may include a dopant.

The matrix may include a paraelectric material.

The vertical NAND flash memory device may include a substrate, where each cell array of the plurality of cell arrays may be arranged perpendicularly to the substrate.

A channel hole extending in a direction perpendicular to the substrate may be inward relative to the channel layer.

The channel hole may be filled with a filling insulating layer.

The channel layer and the charge trap layer may have a cylindrical shape surrounding the channel hole.

The vertical NAND flash memory device may include a tunneling barrier layer provided between the channel layer and the charge trap layer.

The plurality of gate electrodes may be spaced apart from each other in the direction perpendicular to the substrate, and where each gate electrode of the plurality of gate electrodes surrounds the charge trap layer.

The vertical NAND flash memory device may include a blocking insulating layer provided between the charge trap layer and the plurality of gate electrodes.

According to an aspect of the disclosure, an electronic device may include a vertical NAND flash memory device including a plurality of cell arrays, where each cell array of the plurality of cell arrays may include a channel layer, a charge trap layer provided on the channel layer, the charge trap layer including a matrix including a dielectric and a charge trap material in the matrix and including nanocrystals, and a plurality of gate electrodes provided on the charge trap layer.

According to an aspect of the disclosure, a vertical NAND flash memory device may include a substrate, and a plurality of cell arrays arranged perpendicularly to the substrate, where each cell array of the plurality of cell arrays may include a channel layer, a charge trap layer provided on the channel layer, the charge trap layer including a matrix including a dielectric and a charge trap material in the matrix and including nanocrystals, and a plurality of gate electrodes provided on the charge trap layer.

A channel hole extending in a direction perpendicular to the substrate may be inward relative to the channel layer.

The channel hole may be filled with a filling insulating layer.

The channel layer and the charge trap layer may have a cylindrical shape surrounding the channel hole.

The vertical NAND flash memory device may include a tunneling barrier layer provided between the channel layer and the charge trap layer.

The plurality of gate electrodes may be spaced apart from each other in the direction perpendicular to the substrate, and each gate electrode of the plurality of gate electrodes surrounds the charge trap layer.

The vertical NAND flash memory device may include a blocking insulating layer provided between the charge trap layer and the plurality of gate electrodes.

The charge trap material may include anti-ferroelectric nanocrystals or ferroelectric nanocrystals.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram of a vertical NAND flash memory device according to an embodiment;

FIG. 2 is a cross-sectional view of a cell array illustrated in FIG. 1 according to an embodiment;

FIG. 3 is a diagram of a portion of a memory cell illustrated in FIG. 2 according to an embodiment;

FIG. 4A is a diagram of a relationship between an electric field E and polarization P applied to ferroelectric, according to an embodiment;

FIG. 4B is a diagram of a relationship between charges Q and energy U of the ferroelectric according to an embodiment;

FIG. 5A is a schematic diagram of a relationship between an electric field E and polarization P applied to anti-ferroelectric, according to an embodiment;

FIG. 5B is a diagram of a relationship between charges Q and energy U of the anti-ferroelectric according to an embodiment;

FIG. 6A is a band diagram illustrating a program operation of a memory cell having a charge trap layer with anti-ferroelectric nanocrystals (AFE-NC) according to an embodiment;

FIG. 6B is a band diagram illustrating a program operation of the memory cell having a charge trap layer without AFE-NC;

FIG. 6C is a band diagram illustrating an erase operation of the memory cell having a charge trap layer with AFE-NC according to an embodiment;

FIG. 6D is a band diagram illustrating an erase operation of the memory cell having a charge trap layer without AFE-NC according to an embodiment; and

FIG. 7 is a diagram of a device architecture applicable to an electronic device according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

The disclosure will now be described more fully with reference to the accompanying drawings, in which embodiments of the disclosure are shown. In the drawings, like reference numerals refer to like elements throughout and sizes of constituent elements may be exaggerated for convenience of explanation and the clarity of the specification. Also, embodiments described herein may have different forms and should not be construed as being limited to the descriptions set forth herein.

It will also be understood that when an element is referred to as being “on” or “above” another element, the element may be above, below, on the left, or on the right of the other element and in direct contact with the other element or other intervening elements may be present. The singular forms include the plural forms unless the context clearly indicates otherwise. It should be understood that, when a part “comprises” or “includes” an element, unless otherwise defined, other elements are not excluded from the part and the part may further include other elements.

The use of the terms “a” and “an” and “the” and similar referents are to be construed to cover both the singular and the plural. The steps of all methods described herein can be performed in any suitable order unless otherwise indicated herein or otherwise clearly contradicted by context, and are not limited to the described order.

Also, in the specification, the term “units” or “modules” denote units or modules that process at least one function or operation, and may be realized by hardware, software, or a combination of hardware and software.

Furthermore, the connecting lines, or connectors illustrated in the various figures presented are intended to represent exemplary functional relationships and/or physical or logical couplings between the various elements. It should be noted that many alternative or additional functional relationships, physical connections or logical connections may be present in a practical device.

The use of any and all examples, or exemplary language (e.g., “such as”) provided herein, is intended merely to better illuminate the disclosure and does not pose a limitation on the scope of the disclosure unless otherwise claimed.

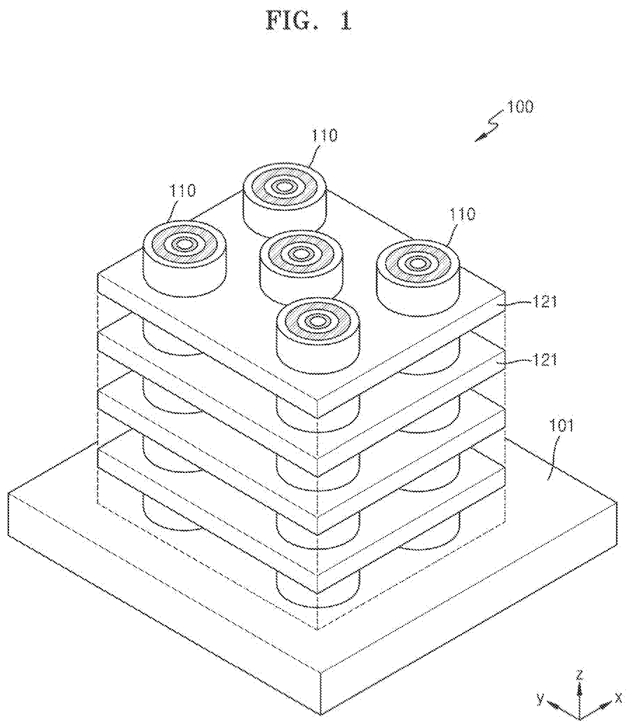

FIG. 1 is a diagram of a vertical NAND flash memory device according to an embodiment.

Referring to FIG. 1, the vertical NAND flash memory device 100 includes a plurality of cell arrays (e.g., cell arrays 110) arranged on a substrate 101. Each cell array 110 may be provided to extend in a direction perpendicular to the substrate 101 (z-axis direction in FIG. 1). The plurality of cell arrays may be arranged on the substrate 101 in various forms.

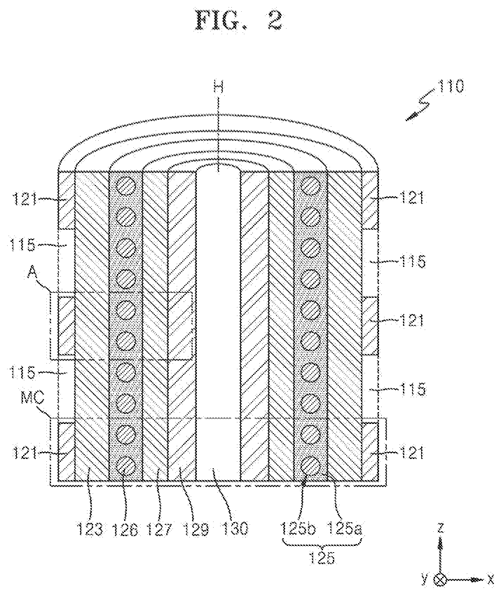

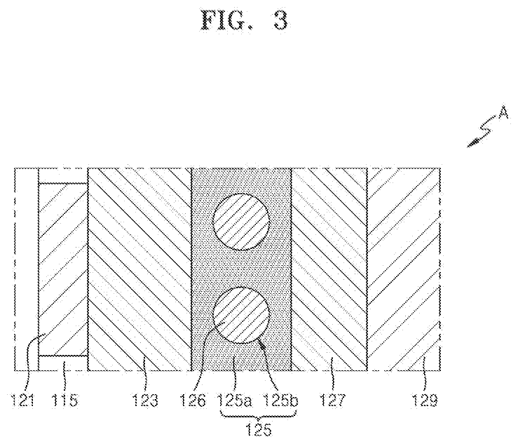

FIG. 2 is a cross-sectional view of a cell array illustrated in FIG. 1 according to an embodiment. FIG. 3 is a diagram of a portion of a memory cell illustrated in FIG. 2 according to an embodiment. That is, FIG. 2 illustrates a cross-section of each cell array 110 illustrated in FIG. 1, and FIG. 3 is an enlarged view of a major portion A of a memory cell MC illustrated in FIG. 2.

Referring to FIGS. 1 and 2, the cell array 110 includes a plurality of memory cells MC stacked in the direction perpendicular to the substrate 101 (z-axis direction). The cell array 110 may include a plurality of gate electrodes 121 spaced apart from each other and stacked in the direction perpendicular to the substrate 101. The cell array 110 may include a blocking insulating layer 123, a charge trap layer 125, a tunneling barrier layer 127, and a channel layer 129 that are sequentially provided inward relative to the gate electrodes 121 and parallel to the substrate 101. Each of the blocking insulating layer 123, the charge trap layer 125, the tunneling barrier layer 127, and the channel layer 129 may be provided to extend perpendicularly to the substrate 101 and may be shared by the plurality of memory cells MC.

Each memory cell MC may include a gate electrode 121, and the blocking insulating layer 123, the charge trap layer 125, the tunneling barrier layer 127, and the channel layer 129 that are provided to correspond to the gate electrode 121. A source and a drain may be provided in the channel layer 129 positioned in a lower portion and an upper portion of each memory cell MC, and a channel corresponding to the gate electrode 121 may be provided in the channel layer 129 between the source and the drain. When a voltage is applied to the gate electrode 121 of each memory cell MC, charges flowing between the source and the drain in the channel layer 129 corresponding to the gate electrode 121 may pass through the tunneling barrier layer 127 and captured in the charge trap layer 125 to thereby store information.

Interlayer insulating layers 115 and gate electrodes 121 are alternately stacked on the substrate 101 in the direction perpendicular to the substrate 101. Each interlayer insulating layer 115 and each gate electrode 121 may be provided parallel to the substrate 101. The substrate 101 may include various materials. For example, the substrate 101 may include a single crystal silicon substrate, a compound semiconductor substrate, or a silicon on insulator (SOI) substrate, but is not limited thereto. In addition, the substrate 101 may further include, for example, an impurity region formed by doping, an electronic element such as a transistor, or a periphery circuit for selecting and controlling memory cells storing data.

The gate electrode 121 controls a corresponding channel layer 129, and a word line may be electrically connected to the gate electrode 121. The gate electrode 121 may include, for example, a metal material having excellent electrical conductivity such as gold (Au), a metal nitride, impurity-doped silicon, or a two-dimensional conductive material. However, this is merely an example, and the gate electrode 121 may also include various other materials. The interlayer insulating layer 115 may act as a spacer layer for insulation between the gate electrodes 121. The interlayer insulating layer 115 may include, for example, silicon oxide or silicon nitride, but is not limited thereto.

A channel hole H is formed to pass through the interlayer insulating layers 115 and the gate electrodes 121 in the direction perpendicular to the substrate 101 (z-axis direction). The channel hole H may have a circular cross-section, for example.

The blocking insulating layer 123, the charge trap layer 125, the tunneling barrier layer 127, and the channel layer 129 are sequentially provided on an inner wall of the channel hole H. Each of the blocking insulating layer 123, the charge trap layer 125, the tunneling barrier layer 127, and the channel layer 129 may be formed to have a cylindrical shape extending in the direction perpendicular to the substrate 101. A filling insulating layer 130 may be provided inward relative to the channel layer 129 to fill the channel hole H. The filling insulating layer 130 may include, for example, silicon oxide or air, but is not limited thereto.

The channel layer 129 may include a semiconductor material. For example, the channel layer 129 may include, for example, Si, Ge, SiGe, Group III-V semiconductor, or the like. Also, the channel layer 129 may include, for example, an oxide semiconductor, a nitride semiconductor, a nitrogen oxide semiconductor, a two-dimensional (2D) semiconductor material, quantum dots, or an organic semiconductor. The oxide semiconductor may include, for example, InGaZnO, and the like, 2D semiconductor material may include, for example, transition metal dichalcogenide (TMD) or graphene, and the quantum dots may include colloidal quantum dots, a nanocrystal structure, and the like. However, this is only an example, and the embodiments are not limited thereto.

The channel layer 129 may further include a dopant. The dopant may include a p-type dopant or an n-type dopant. The p-type dopant may include, for example, a Group III element such as B, Al, Ga, and In, and the n-type dopant may include a Group V element, such as P, As, and Sb.

The blocking insulating layer 123, the charge trap layer 125, and the tunneling barrier layer 127 are provided between the gate electrodes 121 and the channel layer 129. The blocking insulating layer 123 is provided on the inner wall of the channel hole H to contact the interlayer insulating layers 115 and the gate electrodes 121. The blocking insulating layer 123 may include, for example, silicon oxide or metal oxide, but is not limited thereto. The tunneling barrier layer 127 includes a layer through which charges are tunneled, and may include, for example, silicon oxide or metal oxide, but is not limited thereto.

The charge trap layer 125 is provided between the blocking insulating layer 123 and the tunneling barrier layer 127. The charge trap layer 125 includes a matrix 125a and a charge trap material 125b provided inside the matrix 125a. The matrix 125a may include a different dielectric material from that of the charge trap material 125b. For example, the matrix 125a may include a paraelectric material. For example, the matrix 125a may include SiO₂, doped SiO₂, HfO₂, ZrO₂, and the like. HfO₂ or ZrO₂ may have a monoclinic crystal structure.

The charge trap material 125b may include a plurality of nanocrystals 126 dispersed in the matrix 125a. The nanocrystals 126 may include a ferroelectric or anti-ferroelectric material.

A ferroelectric material has a spontaneous dipole (electric dipole) (e.g. spontaneous polarization) due to non-centrosymmetric charge distribution in a unit cell in a crystallized material structure. Ferroelectric materials have remnant polarization by dipoles even in the absence of an external electric field. In addition, the direction of polarization may be switched on a domain-by-domain basis by an external electric field.

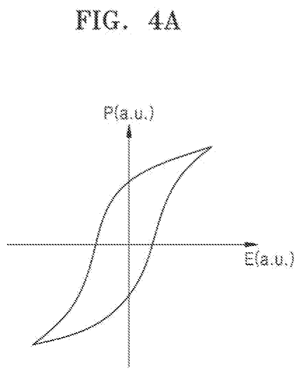

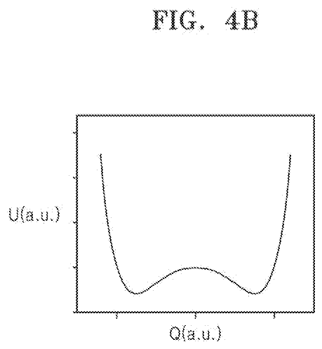

FIG. 4A is a diagram of a relationship between an electric field E and polarization P applied to ferroelectric, according to an embodiment. FIG. 4B is a diagram of a relationship between charges Q and energy U of the ferroelectric according to an embodiment.

Referring to FIGS. 4A and 4B, the charge Q-vs-energy U graph of the ferroelectric has a well shape on both, left and right sides. The two well shapes correspond to two stable polarization states, and this graph shape denotes a hysteresis behavior.

An anti-ferroelectric material may include an array of electrical dipoles, but may have a remnant polarization of zero or close to zero. In the absence of an electric field, the directions of adjacent dipoles are reversed and polarization is canceled, and thus, the overall spontaneous and the remnant polarization may be zero or close to zero. However, polarization characteristics and switching characteristics may be exhibited in a state in which an external electric field is applied.

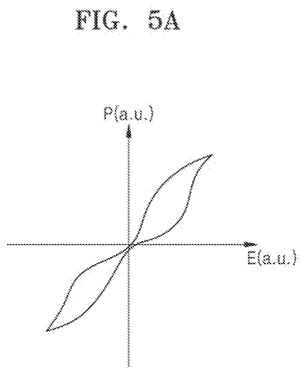

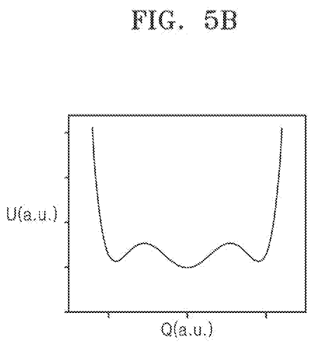

FIG. 5A is a schematic diagram of a relationship between an electric field E and polarization P applied to anti-ferroelectric, according to an embodiment. FIG. 5B is a diagram of a relationship between charges Q and energy U of the anti-ferroelectric according to an embodiment. Referring to FIGS. 5A and 5B, the charge Q-vs-energy U graph of the anti-ferroelectric has a different curve shape from that of the ferroelectric.

The charge trap material 125b may include a flurite-based material, a perovskite-based material, or a wurtzite-based material. Flurite-based materials may include, for example, undoped HfO₂ or ZrO₂. HfO₂ or ZrO₂ may have a crystal structure of a tetragonal system or an orthorhombic system. The tetragonal crystal structure may have anti-ferroelectricity, and the orthorhombic crystal structure may have ferroelectricity. Undoped HfO₂ has a stable tetragonal crystal structure, but may also have an orthorhombic crystal structure, depending on the grain size. Undoped ZrO₂ may have a stable tetragonal crystal structure. Undoped HfO₂ or ZrO₂ may include, for example, nanocrystals having a grain size of about 1 nm to about 3 nm, but is not limited thereto.

Flurite-based materials may include, for example, HfO₂ or ZrO₂ including dopants. The dopants may include, for example, at least one of Al, Ga, Co, Ni, Mg, In, La, Y, Nd, Sm, Er, Sr, Ba, Gd, Ge, N, and Si. However, the above are only an example. HfO₂ or ZrO₂ including a dopant may have a tetragonal crystal structure having anti-ferroelectricity or an orthorhombic crystal structure having ferroelectricity, depending on the grain size and doping concentration. The smaller the grain size and the higher the doping concentration, the more stable is the tetragonal crystal structure, and the larger the grain size and the lower the doping concentration, the more stable is the orthorhombic crystal structure.

HfO₂ or ZrO₂ doped with a dopant may include nanocrystals having a larger grain size than the undoped HfO₂ or ZrO₂ described above. For example, HfO₂ or ZrO₂ doped with a dopant may have a grain size of about 4 nm to about 7 nm (for example, 4 nm to 5 nm), but is not limited thereto.

A dopant concentration may vary according to the type of dopant. For example, when the dopant is Si, a doping concentration thereof may be about 1 at % (atomic percent) to about 5 at %. However, the disclosure is not limited thereto.

Perovskite-based materials may include a material having a composition of ABO₃ (where A and B are metal elements). Perovskite-based materials may include, for example, at least one of PbZrO₃, PbTiO₃, BaTiO₃, SrTiO₃, and CaTiO₃. However, the disclosure is not limited thereto. Perovskite-based materials may have a tetragonal crystal structure having anti-ferroelectricity or an orthorhombic crystal structure having ferroelectricity, depending on the composition ratio of constituent elements. Wurtzite-based materials may include undoped AlN, GaN or InN or may include AlN, GaN or InN including a dopant.

As a method of forming the charge trap layer 125 including the matrix 125a including a dielectric and the charge trap material 125b including the nanocrystals 126 dispersed in the matrix 125a, spinodal decomposition or nucleation growth may be used. For example, when a ratio of HfO/(HfO+SiO) in a HfO—SiO solid solution is about 35 at % to about 95 at %, and heat treatment is performed at a temperature of about 1300° C. to about 1500° C., by spinodal decomposition, HfO₂ nanocrystals doped with Si at about 3 at % to about 5 at % and a SiO₂ matrix doped with Hf at about 35 at % may be formed. The spinodal decomposition may occur when the formation energy (e.g., the Gibbs free-energy change (ΔG)) due to mixing of HfO₂ and SiO₂ is greater than 0 in a certain temperature range. Si-doped HfO₂ nanocrystals have an anti-ferroelectric tetragonal crystal structure and may have a grain size of about 3 nm to about 4 nm.

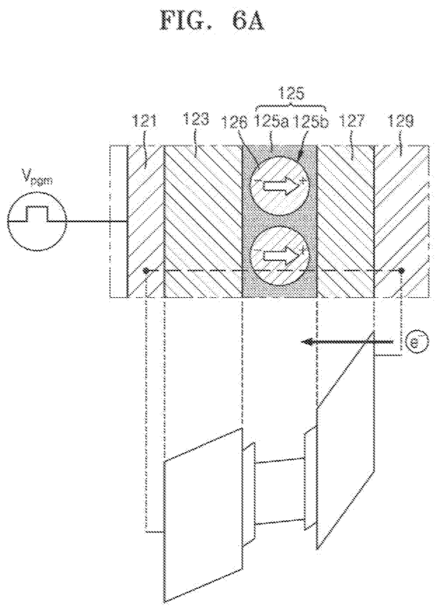

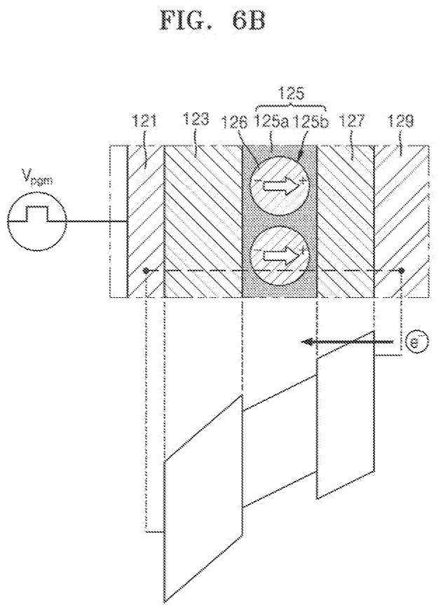

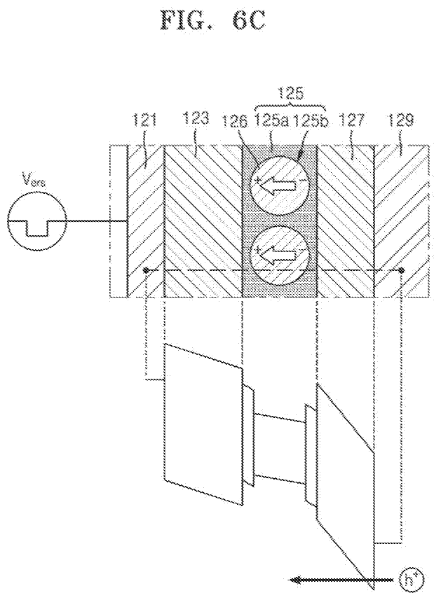

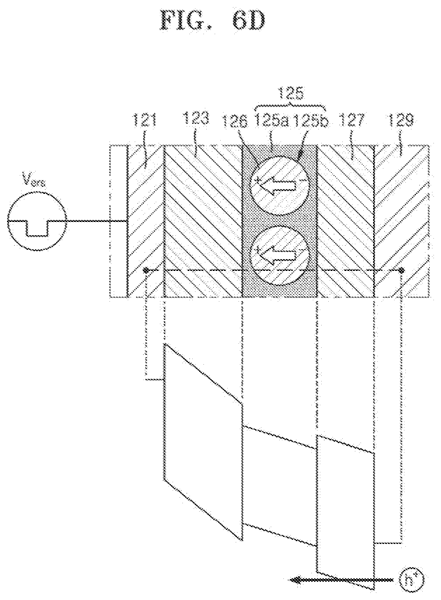

FIG. 6A is a band diagram illustrating a program operation of the memory cell MC illustrated in FIG. 3 having a charge trap layer with anti-ferroelectric nanocrystals (AFE-NC) according to an embodiment. FIG. 6B is a band diagram illustrating a program operation of the memory cell MC illustrated in FIG. 3 having a charge trap layer without AFE-NC according to an embodiment. FIG. 6C is a band diagram illustrating an erase operation of the memory cell MC illustrated in FIG. 3 having a charge trap layer with AFE-NC according to an embodiment. FIG. 6D is a band diagram illustrating an erase operation of the memory cell MC illustrated in FIG. 3 having a charge trap layer without AFE-NC according to an embodiment. FIGS. 6A and 6B illustrate a program operation of the memory cell MC illustrated in FIG. 3.

Referring to FIGS. 6A and 6B, when a positive (+) program voltage V_{pgm} is applied to the gate electrode 121 from the outside, polarization switching due to anti-ferroelectric or ferroelectric switching occurs in the nanocrystals 126 of the charge trap material 125b, and accordingly, a permittivity of the nanocrystals 126 rapidly increases. Thus, most of the program voltage V_{pgm} may be applied to the tunneling barrier layer 127. Moreover, positive and negative charges due to polarization in the nanocrystals 126 may further amplify an electric field applied to the tunneling barrier layer 127. Accordingly, electrons in the channel layer 129 may easily pass through the tunneling barrier layer 127 and be stored in the nanocrystals 126 of the charge trap material 125b. Since an external voltage required for electrons to pass through the tunneling barrier layer 127 is set, in the memory cell MC according to the embodiment, a program voltage may be lowered by the nanocrystals 126 having anti-ferroelectricity or ferroelectricity (e.g., as reflected in the band diagram of FIG. 6A versus the band diagram of FIG. 6B).

FIGS. 6C and 6D illustrates an erase operation of the memory cell MC illustrated in FIG. 3.

Referring to FIGS. 6C and 6D, when a negative (−) erase voltage Vₑᵣₛ is applied to the gate electrode 121 from the outside, polarization switching occurs in an opposite direction to that of the program operation in the nanocrystals 126 of the charge trap material 125b. Accordingly, the permittivity of the nanocrystals 126 increases rapidly, and most of the erase voltage Vₑᵣₛ may be applied to the tunneling barrier layer 127. Moreover, an electric field applied to the tunneling barrier layer 127 may be further amplified by the positive and negative charges of the polarization generated in the nanocrystals 126. Thus, holes in the channel layer 129 may easily pass through the tunneling barrier layer 127 and be stored in the nanocrystals 126 of the charge trap material 125b. Since an external voltage required for holes to pass through the tunneling barrier layer 127 is set, an erase voltage may be lowered by the nanocrystals 126 having anti-ferroelectricity or ferroelectricity, in the memory cell MC according to the embodiment (e.g., as reflected in the band diagram of FIG. 6C versus the band diagram of FIG. 6D).

As described above, in the vertical NAND flash memory device 100 according to an embodiment, the charge trap material 125b of the charge trap layer 125 may include the plurality of nanocrystals 126 having anti-ferroelectricity or ferroelectricity, and accordingly, the program voltage and the erase voltage may be lowered, and a memory window may also be improved. In addition, as the nanocrystals 126 are separated from each other by the matrix 125a composed of a dielectric material in which a charge transfer hardly occurs, it is difficult for charges stored in the nanocrystals 126 to move between the memory cells MC, and thus, the data retention characteristics of the memory cell MC may also be improved.

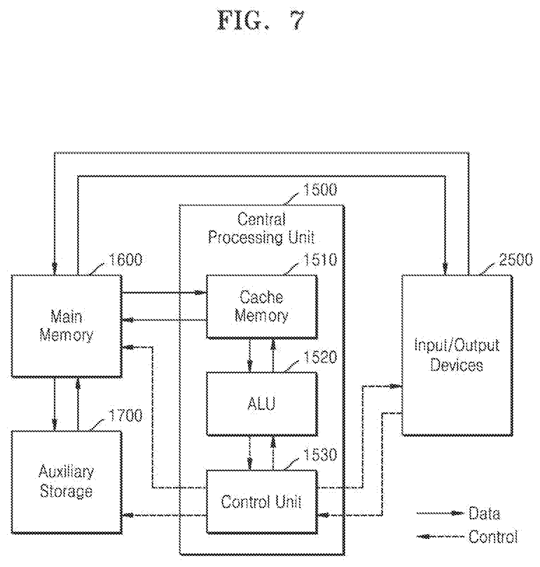

The vertical NAND flash memory device 100 described above may be used for data storage in various electronic devices. FIG. 7 is a diagram of a device architecture applicable to an electronic device according to an embodiment.

Referring to FIG. 7, a cache memory 1510, an arithmetic logic unit (ALU) 1520, and a control unit 1530 may configure a central processing unit (CPU) 1500, and the cache memory 1510 may include static random access memory (SRAM). Apart from the CPU 1500, a main memory 1600 and an auxiliary storage 1700 may be provided. The main memory 1600 may include a dynamic RAM (DRAM) device, and the auxiliary storage 1700 may include the vertical NAND flash memory device 100 described above. In some cases, the device architecture may be implemented in a form in which computing unit devices and memory unit devices are adjacent to each other in a single chip without distinguishing sub-units.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A vertical NAND flash memory device, comprising:
a plurality of cell arrays,
wherein each cell array of the plurality of cell arrays comprises:
a channel layer;
a charge trap layer provided on the channel layer, the charge trap layer comprising:
a matrix comprising a dielectric; and
a charge trap material in the matrix and comprising anti-ferroelectric nanocrystals or ferroelectric nanocrystals; and
a plurality of gate electrodes provided on the charge trap layer.

2. The vertical NAND flash memory device of claim 1, wherein the charge trap material further comprises a flurite-based material, a perovskite-based material, or a wurtzite-based material.

3. The vertical NAND flash memory device of claim 2, wherein the flurite-based material comprises HfO₂ or ZrO₂.

4. The vertical NAND flash memory device of claim 3, wherein the flurite-based material further comprises a dopant.

5. The vertical NAND flash memory device of claim 4, wherein the dopant comprises at least one of Al, Ga, Co, Ni, Mg, In, La, Y, Nd, Sm, Er, Sr, Ba, Gd, Ge, N, and Si.

6. The vertical NAND flash memory device of claim 3, wherein the flurite-based material comprises an anti-ferroelectric material having a tetragonal system structure or a ferroelectric material having an orthorhombic system structure.

7. The vertical NAND flash memory device of claim 6, wherein the flurite-based material comprises nanocrystals having a grain size of about 1 nm to about 7 nm.

8. The vertical NAND flash memory device of claim 2, wherein the perovskite-based material comprises a material having a composition of ABO₃, and
wherein A and B comprise metal elements.

9. The vertical NAND flash memory device of claim 8, wherein the perovskite-based material comprises at least one of PbZrO₃, PbTiO₃, BaTiO₃, SrTiO₃ and CaTiO₃.

10. The vertical NAND flash memory device of claim 2, wherein the wurtzite-based material comprises AlN, GaN or InN.

11. The vertical NAND flash memory device of claim 10, wherein the wurtzite-based material further comprises a dopant.

12. The vertical NAND flash memory device of claim 1, wherein the matrix further comprises a paraelectric material.

13. The vertical NAND flash memory device of claim 1, further comprising a substrate,
wherein each cell array of the plurality of cell arrays is arranged perpendicularly to the substrate.

14. The vertical NAND flash memory device of claim 13, wherein a channel hole extending in a direction perpendicular to the substrate is inward relative to the channel layer.

15. The vertical NAND flash memory device of claim 14, wherein the channel hole is filled with a filling insulating layer.

16. The vertical NAND flash memory device of claim 15, wherein the channel layer and the charge trap layer have a cylindrical shape surrounding the channel hole.

17. The vertical NAND flash memory device of claim 16, further comprising a tunneling barrier layer provided between the channel layer and the charge trap layer.

18. The vertical NAND flash memory device of claim 16, wherein the plurality of gate electrodes are spaced apart from each other in the direction perpendicular to the substrate, and
wherein each gate electrode of the plurality of gate electrodes surrounds the charge trap layer.

19. The vertical NAND flash memory device of claim 18, further comprising a blocking insulating layer provided between the charge trap layer and the plurality of gate electrodes.

20. An electronic device, comprising
a vertical NAND flash memory device comprising a plurality of cell arrays, wherein each cell array of the plurality of cell arrays comprises:
a channel layer;
a charge trap layer provided on the channel layer, the charge trap layer comprising:
a matrix comprising a dielectric; and
a charge trap material in the matrix and comprising nanocrystals; and
a plurality of gate electrodes provided on the charge trap layer.
